(19) United States
(12) Patent Application Publication
(10) Pub. No.: US 2023/0252198 A1
(43) Pub. Date: Aug. 10, 2023

(54) STYLIZATION-BASED FLOOR PLAN GENERATION

(71) Applicant: ACCENTURE GLOBAL SOLUTIONS LIMITED, Dublin 4 (IE)

(72) Inventors: Abhinav UPADHYAY, Hazaribag (IN); Alpana DUBEY, Bangalore (IN)

(73) Assignee: ACCENTURE GLOBAL SOLUTIONS LIMITED, Dublin 4 (IE)

(21) Appl. No.: 18/108,375

(22) Filed: Feb. 10, 2023

(30) Foreign Application Priority Data
Feb. 10, 2022 (IN) 202211007031
Jul. 8, 2022 (IN) 202211039342

(51) Int. Cl. G06F 30/13; G06F 30/27

(52) U.S. Cl. CPC G06F 30/13; G06F 30/27

(57) ABSTRACT

In some examples, stylization-based floor plan generation may include receiving, for a floor plan that is to be generated, a layout graph for which user constraints are encoded as a plurality of room types. The user constraints may include spatial connections therebetween. Based on the layout graph, embedding vectors may be generated for each room type of the plurality of room types. Bounding boxes and segmentation masks may be determined for each room embedding from the layout graph, and based on an analysis of the embedding vectors for each room type of the plurality of room types. A space layout may be generated by combining the bounding boxes and the segmentation masks. A floor plan may be generated based on an analysis of the space layout and an input boundary feature map.

### PRIORITY

This application is a Non-Provisional Application of commonly assigned and co-pending Indian Patent Application Serial Number 202211039342, filed Jul. 8, 2022, and co-pending Indian Patent Application Serial Number 202211007031, filed Feb. 10, 2022, the disclosures of which are hereby incorporated by reference in their entireties.

### BACKGROUND

With respect to floor plan design of residential as well as non-residential facilities, tools, such as computer-aided design (CAD) tools, may be used to design a floor plan. Depending on the complexity of the floor plan design, various levels of expertise may be required for utilization of such tools. In an example of a floor plan design, an architect may obtain the requirements from a client in the form of room types, number of rooms, room sizes, plot boundary, the connection between rooms, etc., sketch out rough floor plans and collect feedback from the client, refine the sketched plans, and design and generate the floor plan using CAD tools. The experience of the architect may become a significant factor in the quality of the floor plan design.

### BRIEF DESCRIPTION OF DRAWINGS

Features of the present disclosure are illustrated by way of example and not limited in the following figure(s), in which Ike numerals indicate like elements, in which:

FIG. 1 illustrates a layout of a stylization-based floor plan generation apparatus in accordance with an example of the present disclosure;

FIG. 2 illustrates an architecture of the stylization-based floor plan generation apparatus of FIG. 1, in accordance with an example of the present disclosure;

FIG. 3 illustrates floor parsing of computer-aided design (CAD) drawings for the stylization-based floor plan generation apparatus of FIG. 1, in accordance with an example of the present disclosure;

FIG. 4A illustrates further details of the architecture of the stylization-based floor plan generation apparatus of FIG. 1, in accordance with an example of the present disclosure;

FIG. 4B illustrates details of a spatial attention block of the stylization-based floor plan generation apparatus of FIG. 1, in accordance with an example of the present disclosure;

FIG. 5 illustrates details of an attention component of the stylization-based floor plan generation apparatus of FIG. 1, in accordance with an example of the present disclosure;

FIG. 6 illustrates results of parsing of CAD drawings for the stylization-based floor plan generation apparatus of FIG. 1, in accordance with an example of the present disclosure;

FIG. 7 illustrates a dataset for the stylization-based floor plan generation apparatus of FIG. 1, in accordance with an example of the present disclosure;

FIG. 8 illustrates pre-processed data for the stylization-based floor plan generation apparatus of FIG. 1, in accordance with an example of the present disclosure;

FIG. 9 illustrates snapshots to illustrate operation of the stylization-based floor plan generation apparatus of FIG. 1, in accordance with an example of the present disclosure;

FIG. 10 illustrates pre-processing to illustrate operation of the stylization-based floor plan generation apparatus of FIG. 1, in accordance with an example of the present disclosure;

FIG. 11 illustrates pre-processed data to illustrate operation of the stylization-based floor plan generation apparatus of FIG. 1, in accordance with an example of the present disclosure;

FIG. 12 illustrates similar layout extraction to illustrate operation of the stylization-based floor plan generation apparatus of FIG. 1, in accordance with an example of the present disclosure;

FIG. 13 illustrates results to illustrate operation of the stylization-based floor plan generation apparatus of FIG. 1, in accordance with an example of the present disclosure;

FIG. 14 illustrates details of a space layout network analyzer to illustrate operation of the stylization-based floor plan generation apparatus of FIG. 1, in accordance with an example of the present disclosure;

FIG. 15 illustrates a bounding regression network of the space layout network analyzer of the stylization-based floor plan generation apparatus of FIG. 1, in accordance with an example of the present disclosure;

FIG. 16 illustrates a mask regression network of the space layout network analyzer of the stylization-based floor plan generation apparatus of FIG. 1, in accordance with an example of the present disclosure;

FIG. 17 illustrates an output of the stylization-based floor plan generation apparatus of FIG. 1, in accordance with an example of the present disclosure;

FIG. 18 illustrates a message passing network of the stylization-based floor plan generation apparatus of FIG. 1, in accordance with an example of the present disclosure;

FIGS. 19 and 20 illustrate examples of results generated by the stylization-based floor plan generation apparatus of FIG. 1, along with ground truth, in accordance with an example of the present disclosure;

FIG. 21 illustrates an example block diagram for stylization-based floor plan generation in accordance with an example of the present disclosure;

FIG. 22 illustrates a flowchart of an example method for stylization-based floor plan generation in accordance with an example of the present disclosure; and

FIG. 23 illustrates a further example block diagram for stylization-based floor plan generation in accordance with another example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

Stylization-based floor plan generation apparatuses, methods for stylization-based floor plan generation, and non-transitory computer readable media having stored thereon machine readable instructions to provide stylization-based floor plan generation are disclosed herein. The apparatuses, methods, and non-transitory computer readable media disclosed herein provide for generation of a floor plan intuitively with limited knowledge about the design and limited experience with utilization of complex designing tools. The apparatuses, methods, and non-transitory computer readable media disclosed herein provide for floor plan design exploration that is guided by multi-attribute constraints. Further, the apparatuses, methods, and non-transitory computer readable media disclosed herein provide for the transfer of a style of one floor plan to another. In this regard, the apparatuses, methods, and non-transitory computer readable media disclosed herein provide for interactive creation of floor plans by users and/or designers. Yet further, the apparatuses, methods, and non-transitory computer readable media disclosed herein may facilitate interactive floor plan design of a residential or non-residential facility.

For the apparatuses, methods, and non-transitory computer readable media disclosed herein, user inputs in the form of boundary, room types, and spatial relationships may be considered to generate the layout design satisfying these requirements. Based on qualitative and quantitative analysis of metrics such as floor plan layout generation accuracy, realism, and quality, floor plans generated by the apparatuses, methods, and non-transitory computer readable media disclosed herein may provide greater realism and improved quality compared to known techniques.

With respect to floor plan design, a floor plan design for a home or a non-residential building may be perpetually customizable in that the future of the home may understand occupants' needs of space, mood, occasion, and will automatically change itself, and these changes may be perpetual and highly personalized. Further, the floor plan design for a home or a non-residential building may be assistive and protective in that a future home may make necessary accommodations based on specific physical limitations of occupants. The floor plan design for a home or a non-residential building may include a workflow that includes a first step including design ideas where inspiration is obtained from disparate sources, a second step including lifestyle analysis where current home and lifestyle aspects are examined, a third step including sketch design where a rough floor plan is sketched, and a fourth step including computer aided design (CAD) design where CAD tools are used to design the floor plan. Further, with respect to floor plan design, as disclosed herein, tools, such as CAD tools, may be used to design a floor plan. Depending on the complexity of the floor plan design, various levels of expertise may be required for utilization of such tools. In this regard, it is technically challenging to generate a floor plan without expertise in floor plan design or the use of complex designing tools.

In order to address at least the aforementioned technical challenges, the apparatuses, methods, and non-transitory computer readable media disclosed herein may implement a generative model to synthesize floor plans guided by user constraints. User inputs in the form of boundary, room types, and spatial relationships may be analyzed to generate the floor plan design that satisfies these requirements. For example, the apparatuses, methods, and non-transitory computer readable media disclosed herein may receive, as input, a layout graph describing objects (e.g., types of rooms) and their relationships (e.g., connections between rooms, placement of furniture), and generate one or more realistic floor plans corresponding to the layout graph. The apparatuses, methods, and non-transitory computer readable media disclosed herein may utilize a graph convolution network (GCN) to process an input layout graph, which provides embedding vectors for each room type. These vectors may be used to predict bounding boxes and segmentation masks for objects, which are combined to form a space layout. The space layout may be synthesized to an image using a cascaded alignment layer analyzer to generate a floor plan.

In one example, the architecture of the stylization-based floor plan generation apparatus may include a graph convolutional message passing network analyzer, a space layout network analyzer, and a cascaded alignment layer analyzer. The graph convolutional message passing network analyzer may process input graphs and generate embedding vectors for each room type. The space layout network analyzer may predict bounding boxes and segmentation masks for each room embedding, and combine the bounding boxes and the segmentation masks to generate a space layout. The cascaded alignment layer analyzer may synthesize the space layout to generate a floor plan using an input boundary feature map.

The apparatuses, methods, and non-transitory computer readable media disclosed herein may provide an end-to-end trainable network to generate floor plans along with doors and windows from a given input boundary and layout graph. The generated two-dimensional (2D) floor plan may be converted to 2.5D to 3D floor plans. The aforementioned floor plan generation process may also be used to generate floor plans for a single unit or multiple units. For example, in the case of an apartment, a layout of multiple units of different configurations may be generated. The generated floor plan may be utilized to automatically (e.g., without human intervention) control (e.g., by a controller) one or more tools and/or machines related to construction of a structure specified by the floor plan. For example, the tools and/or machines may be automatically guided by the dimensional layout of the floor plan to coordinate and/or verify dimensions and/or configurations of structural features (e.g., walls, doors, windows, etc.) specified by the floor plan. In one example, the generated floor plan may be used to automatically generate 2.5 dimensional (2.5D) or 3D models.

The apparatuses, methods, and non-transitory computer readable media disclosed herein may further provide for the generation of high quality floor plan layouts without any post-processing. For example, compared to known techniques of floor plan generation, the apparatuses, methods, and non-transitory computer readable media disclosed herein may provide a floor plan that is more efficient and easier to build due to the higher quality of the floor plan. In this regard, the apparatuses, methods, and non-transitory computer readable media disclosed herein may provide an end-to-end trainable network to generate floor plans along with doors and windows from a given input boundary and layout graph. The apparatuses, methods, and non-transitory computer readable media disclosed herein may perform stylization of structural elements of a floor plan. For example, the apparatuses, methods, and non-transitory computer eadable media disclosed herein may provide end to end parsing of a floor plan (e.g., CAD or raster format), identify similar floor plans to extract the style, and then apply the style elements to a new boundary to generate the floor plan. In some examples, user inputs (or requirements) in the form of a graph such as a number of rooms, type, size and the input boundary may be analyzed to generate a floor plan based on the user inputs.

For the apparatuses, methods, and non-transitory computer readable media disclosed herein, the elements of the apparatuses, methods, and non-transitory computer readable media disclosed herein may be any combination of hardware and programming to implement the functionalities of the respective elements. In some examples described herein, the combinations of hardware and programming may be implemented in a number of different ways. For example, the programming for the elements may be processor executable instructions stored on a non-transitory machine-readable storage medium and the hardware for the elements may include a processing resource to execute those instructions. In these examples, a computing device implementing such elements may include the machine-readable storage medium storing the instructions and the processing resource to execute the instructions, or the machine-readable storage medium may be separately stored and accessible by the computing device and the processing resource. In some examples, some elements may be implemented in circuitry.

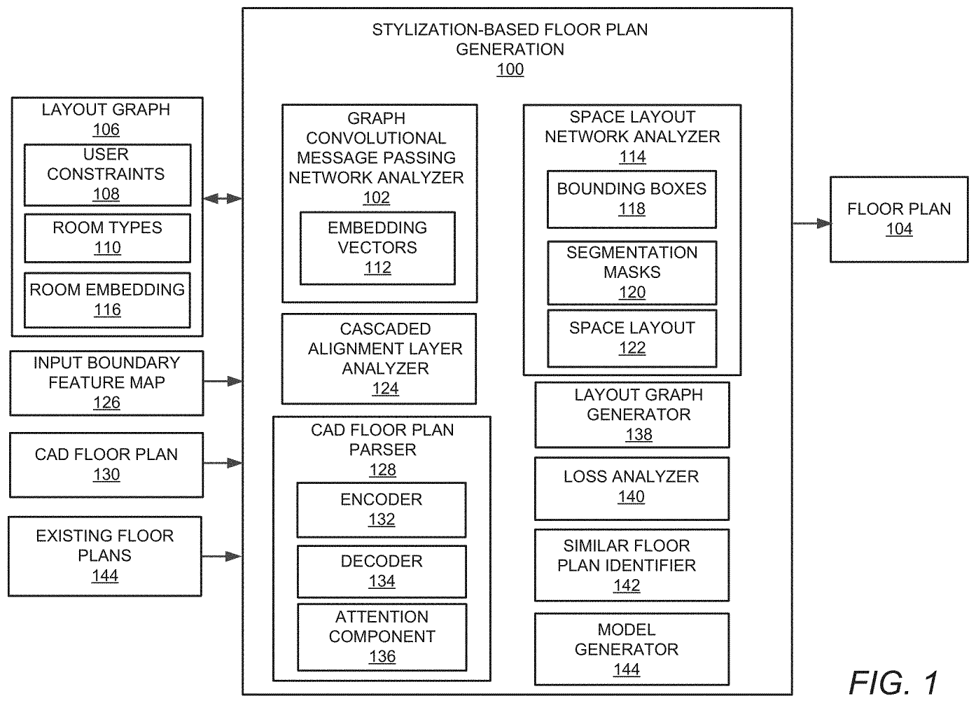

FIG. 1 illustrates a layout of an example stylization-based floor plan generation apparatus (hereinafter also referred to as “apparatus 100”).

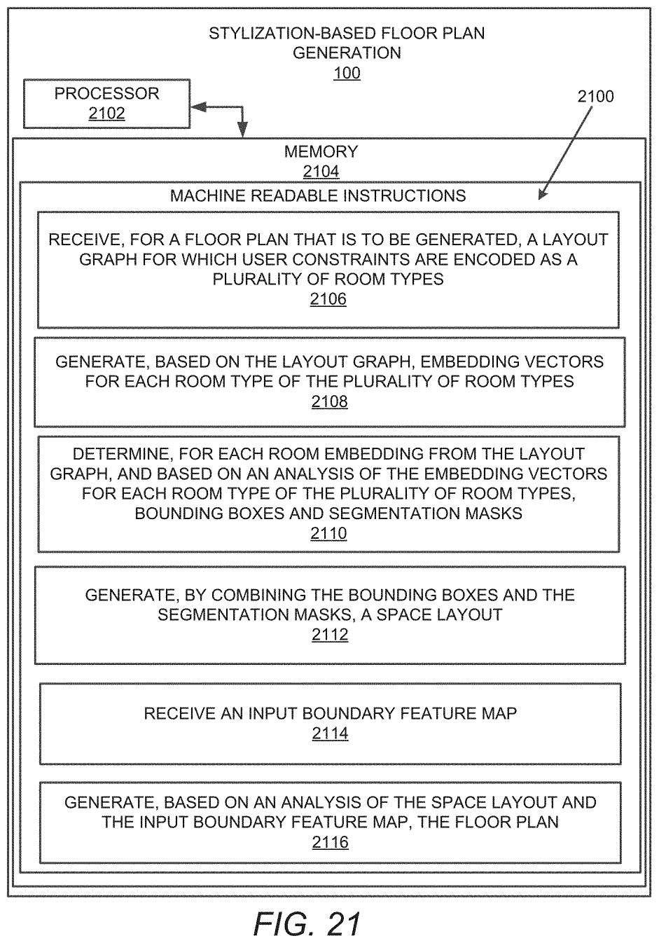

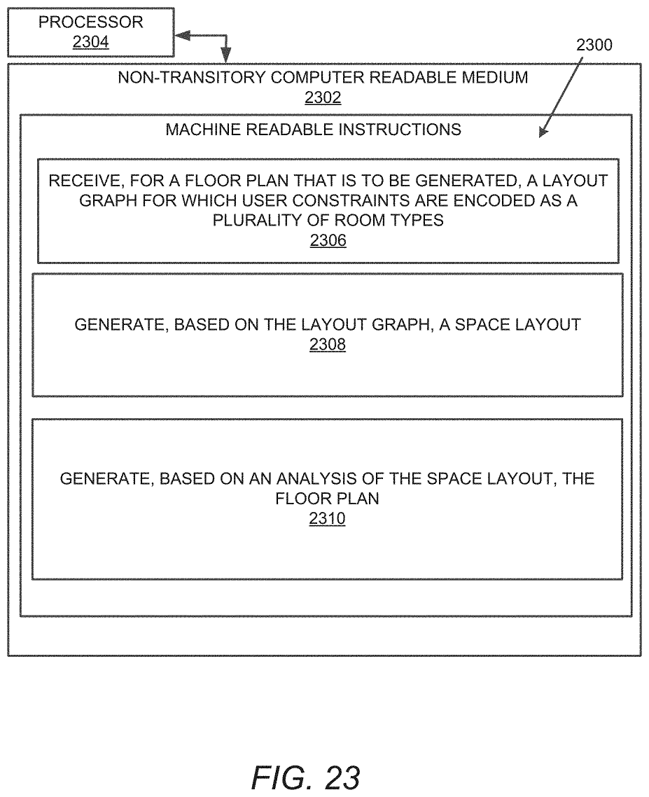

Referring to FIG. 1 the apparatus 100 may include a graph convolutional message passing network analyzer 102 that is executed by at least one hardware processor (e.g., the hardware processor 2102 of FIG. 21, and/or the hardware processor 2304 of FIG. 23) to receive, for a floor plan 104 that is to be generated, a layout graph 106 for which user constraints 108 are encoded as a plurality of room types 110. The user constraints 108 may include spatial connections therebetween. The graph convolutional message passing network analyzer 102 may generate, based on the layout graph 106, embedding vectors 112 for each room type of the plurality of room types 110.

A space layout network analyzer 114 that is executed by at least one hardware processor (e.g., the hardware processor 2102 of FIG. 21, and/or the hardware processor 2304 of FIG. 23) may determine, for each room embedding 116 from the layout graph 106, and based on an analysis of the embedding vectors 112 for each room type of the plurality of room types 110, bounding boxes 118 and segmentation masks 120. The space layout network analyzer 114 may generate, by combining the bounding boxes 118 and the segmentation masks 120, a space layout 122.

A cascaded alignment layer analyzer 124 that is executed by at least one hardware processor (e.g., the hardware processor 2102 of FIG. 21, and/or the hardware processor 2304 of FIG. 23) may receive an input boundary feature map 126. The cascaded alignment layer analyzer 124 may generate, based on an analysis of the space layout 122 and the input boundary feature map 126, the floor plan 104.

A computer-aided design (CAD) floor plan parser 128 that is executed by at least one hardware processor (e.g., the hardware processor 2102 of FIG. 21, and/or the hardware processor 2304 of FIG. 23) may receive a CAD floor plan 130. Further, the CAD floor plan parser 128 may parse the CAD floor plan 130 to determine a room layout for the CAD floor plan 130.

According to examples disclosed herein, the CAD floor plan parser 128 may parse the CAD floor plan 130 to determine the room layout for the CAD floor plan 130 by extracting, by an encoder 132, a plurality of features from the CAD floor plan 130. The CAD floor plan parser 128 may upsample, by a decoder 134, the extracted plurality of features to generate a segmentation image. Further, the CAD floor plan parser 128 may determine, by an attention component 136 and from the segmentation image, semantic information and target features to generate the room layout for the CAD floor plan 130.

According to examples disclosed herein, the attention component 136 may determine the semantic information and the target features by combining low-level feature maps with high-level feature maps.

According to examples disclosed herein, the attention component 136 may determine the semantic information and the target features by multiplying the low-level feature maps by an attention vector.

A layout graph generator 138 that is executed by at least one hardware processor (e.g., the hardware processor 2102 of FIG. 21, and/or the hardware processor 2304 of FIG. 23) may generate, from the room layout, the layout graph 106.

A loss analyzer 140 that is executed by at least one hardware processor (e.g., the hardware processor 2102 of FIG. 21, and/or the hardware processor 2304 of FIG. 23) may analyze, for the generated floor plan, a cross-entropy loss.

A similar floor plan identifier 142 that is executed by at least one hardware processor (e.g., the hardware processor 2102 of FIG. 21, and/or the hardware processor 2304 of FIG. 23) may determine node similarity between the generated floor plan 104 and a plurality of existing floor plans 144. The similar floor plan identifier 142 may generate, based on the determined node similarity between the generated floor plan 104 and the plurality of existing floor plans 144, similarity scores. The similar floor plan identifier 142 may identify, from the generated similarity scores, a highest similarity score. Further, the similar floor plan identifier 142 may identify, based on the highest similarity score, a most similar existing floor plan.

According to examples disclosed herein, the graph convolutional message passing network analyzer 102 may generate, based on the layout graph 106, the embedding vectors 112 for each room type of the plurality of room types 110 by utilizing a plurality of embedding layers to embed room types and relationships between rooms to generate vectors of a specified dimension.

According to examples disclosed herein, the space layout network analyzer 114 may determine, for each room embedding 116 from the layout graph 106, and based on the analysis of the embedding vectors 112 for each room type of the plurality of room types 110, the bounding boxes 118 and the segmentation masks 120 by passing the embedding vectors 112 to a box regression network to predict the bounding boxes 118.

According to examples disclosed herein, the space layout network analyzer 114 may generate, by combining the bounding boxes 118 and the segmentation masks 120, the space layout 122 by multiplying an embedding vector for each room type by an associated mask to generate a plurality of masked embedding shapes. The space layout network analyzer 114 may utilize bi-linear interpolation to modify the masked embedding shapes to a position of associated bounding boxes to generate room layouts. Further, the space layout network analyzer 114 may generate, based on a summation of the room layouts, the space layout 122.

A model generator 144 that is executed by at least one hardware processor (e.g., the hardware processor 2102 of FIG. 21, and/or the hardware processor 2304 of FIG. 23) may generate, based on the floor plan 104, 2.5 dimensional (2.5D) or 3D models. For example, the model generator 144 may receive the floor plan 104 as input, and generate, based on the floor plan 104, 2.5D or 3D models. The 2.5D or 3D models may be displayed to a user of the floor plan 104. In this regard, in another example, the model generator 144 may operate in conjunction with a 3D printer to generate physical 2.5D or 3D models.

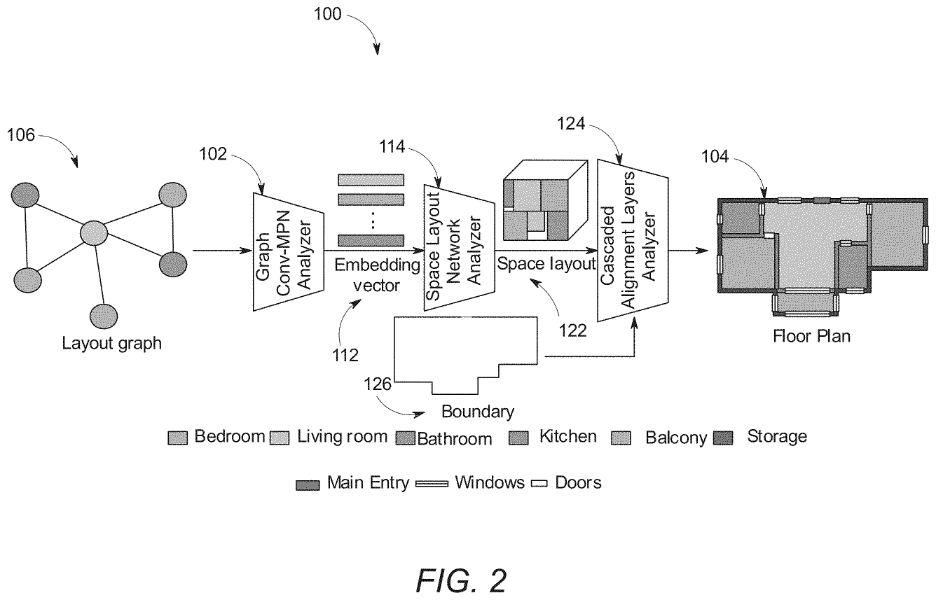

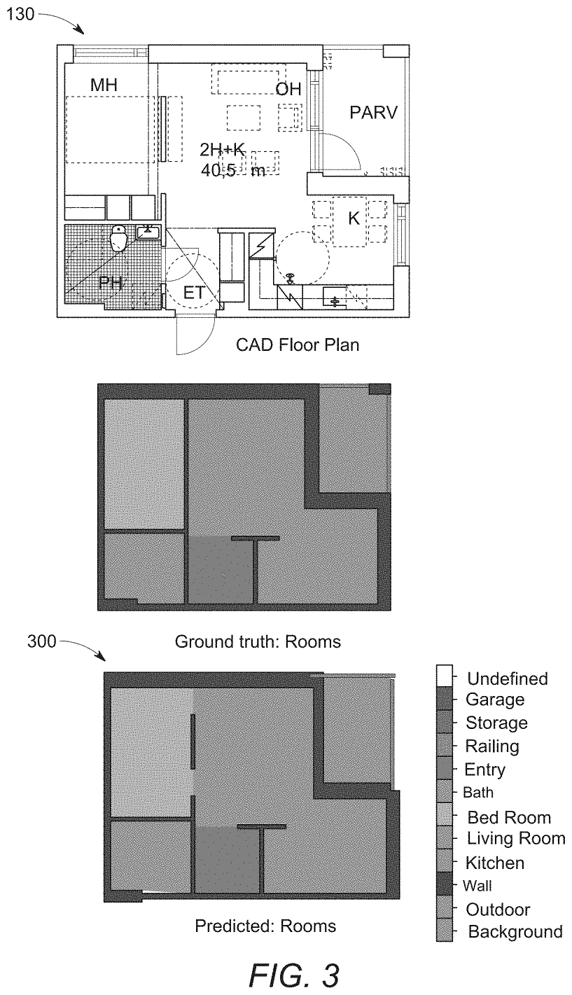

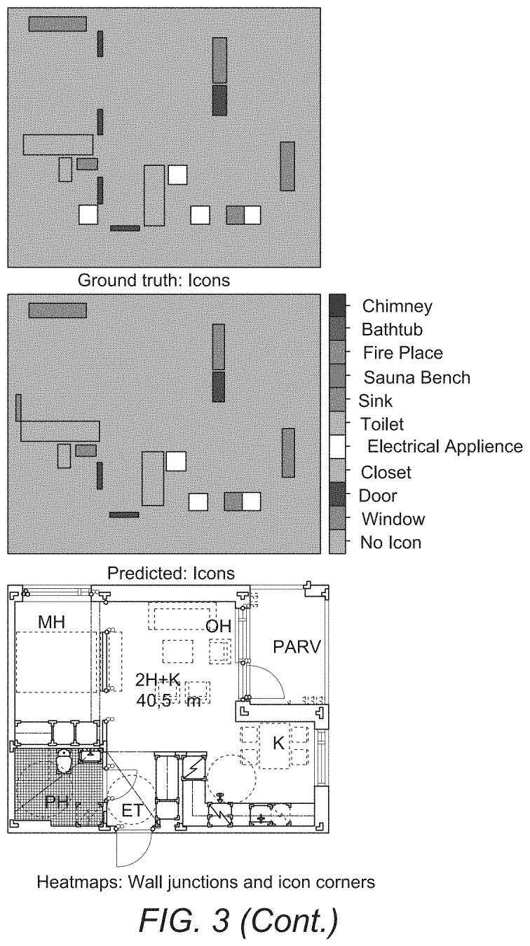

FIG. 2 illustrates an architecture of the apparatus 100, in accordance with an example of the present disclosure. The architecture of FIG. 2 shows a layout graph 106 as input for floor plan generation. The layout graph 106 may be generated, as disclosed herein, by parsing either vector graphics or CAD plans. Parsing of either vector graphics or CAD plans to generate the layout graph 106 is disclosed herein with reference to FIGS. 3-6.

Referring to FIG. 2, the architecture of the apparatus 100 may include the graph convolutional message passing network analyzer 102, the space layout network analyzer 114, and the cascaded alignment layer analyzer 124. The graph convolutional message passing network analyzer 102 may process the layout graph 106 that encodes user constraints as room types and their spatial connections, and generate the embedding vectors 112 for each room type. An embedding vector may denote a compact feature representation for each type of room (e.g., node in the layout graph 106).

With respect to the graph convolutional message passing network analyzer 102, the layout graph 106 may be passed through a series of graph convolution layers (e.g., a message passing network) which generates embedding vectors for each node (e.g., a room). The graph convolutional message passing network analyzer 102 may utilize embedding layers to embed the room types and relationships in the layout graph 106 to produce vectors, for example, of dimension Dᵢₙ=128. Given an input graph with vectors of dimension Dᵢₙ at each node and edge, the graph convolutional message passing network analyzer 102 may determine new vectors of dimension Dₒᵤₜ for each node and edge. Output vectors may be a function of a neighborhood of their corresponding inputs so that each graph convolution layer propagates information along edges of the layout graph 106.

The space layout network analyzer 114 may predict the bounding boxes 118 and the segmentation masks 120 for each room embedding 116 from the layout graph 106, and combine the bounding boxes 118 and the segmentation masks 120 to generate the space layout 122. A bounding box may be used to describe the spatial location of an object. A mask may represent a binary image including zero and non-zero values. A space layout may represent an aggregation of bilinear interpolation of a bounding box and a mask for each room type (e.g., node).

The cascaded alignment layer analyzer 124 may synthesize the space layout 122 to generate the floor plan 104 using the input boundary feature map 126. The graph convolutional message passing network analyzer 102, the space layout network analyzer 114, and the cascaded alignment layer analyzer 124 may be trainable to generate, for example, rooms, walls, doors, and windows.

With respect to a scene graph as disclosed herein, the cascaded alignment layer analyzer 124 may receive the input boundary feature map 126 (e.g., B as a 256×256 image). Further, the graph convolutional message passing network analyzer 102 may receive the layout graph 106 with encoded user-constraints G as input. The cascaded alignment layer analyzer 124 may generate the floor plan 104 (e.g., floor plan layout L) as output. In some examples, the input boundary feature map 126 may be represented as a 256×256 image. The nodes of the layout graph 106 may be denoted room types, and the edges may be denoted connections between the rooms. Each node may be represented as a tuple (rᵢ, lᵢ, sᵢ); where rᵢ∈R^{d}^{₁} is a room embedding (R being the possible categories of room types), lᵢ∈(0,1)^{d}^{₂} is a location vector, and sᵢ∈(0,1)^{d}^{₃} is a size vector. In some examples, the embedding size d₁ may be set to 128, d₂ may be set to 25 to denote a coarse image location using a 5×5 grid, and d₃ may be set to 10 to denote the size of a room using different scales.

FIG. 3 illustrates floor parsing of CAD drawings for the apparatus 100, in accordance with an example of the present disclosure.

Referring to FIG. 3, as disclosed herein, the CAD floor plan parser 128 may receive a CAD floor plan 130. Further, the CAD floor plan parser 128 may parse the CAD floor plan 130 to determine a room layout 300 for the CAD floor plan 130.

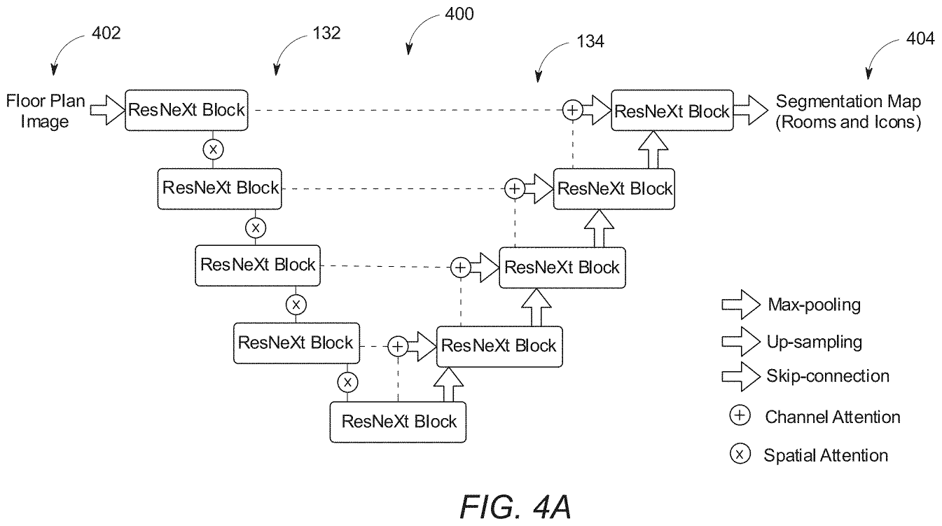

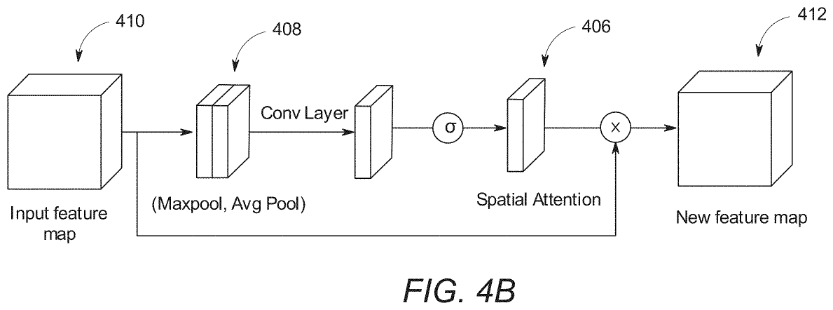

FIG. 4A illustrates further details of the architecture of the apparatus 100, in accordance with an example of the present disclosure. FIG. 4B illustrates details of a spatial attention block of the apparatus 100, in accordance with an example of the present disclosure.

Referring to FIG. 4A, the apparatus 100 may implement a multi-task deep attention-based network 400 to recognize the room-boundary and room-type elements in CAD floor plans, such as the CAD floor plan 130 of FIG. 3. The multi-task deep attention-based network 400 may include the encoder 132, the decoder 134, and the attention component 136 including channel attention and spatial attention. Generally, the encoder 132 may extract features from a floor plan image 402 (e.g., the CAD floor plan 130) using, for example, ResNeXt blocks. The decoder 134 may upsample the extracted feature map from the encoder to generate the segmentation image 404. The attention component 136 may capture high-level semantic information and emphasize target features.

In further detail, the encoder (ResNeXt block) 132 may extract features from the floor plan image 402 and obtain a compact representation of these features through multiple levels. In this regard, a ResNeXt block may be utilized in the encoder 132 to extract features from the floor plan image 402. ResNeXt may repeat a budding block that aggregates a set of transformations with the same topology. Down-sampling may be performed by 2×2 max-pooling operation. During each downsampling, the image size may be reduced and the number of feature channels may be doubled.

With reference to FIGS. 4A and 4B, between each ResNeXt block in the encoder 132, spatial attention may be applied to focus on the informative regions in the feature map. The spatial attention block 406 may utilize the inter-spatial relationship of features. In order to determine spatial attention, at block 408, average-pooling and max-pooling operations may be applied along the channel axis to generate two spatial descriptors, Fₛ^{avg} and Fₛ^{max} respectively as follows:

F′=F⊗σ(f^{conv}(Fₛ^{avg},Fₛ^{max})) Equation (1)

In Equation (1), F may represent the input feature map 410, f^{conv} may represent the convolution operation with a filter size, for example, of 4×4, and σ may represent the activation function. The two spatial descriptors may be concatenated to generate a single feature descriptor. A convolution layer may be applied on the concatenated feature descriptor followed by sigmoid activation to generate a spatial attention map. Element-wise multiplication may be performed between the input feature map and the spatial attention map to generate a new feature map 412 focusing on spatial features. During the element-wise multiplication operation, the spatial attention values may be broadcasted.

The decoder 134 may be used to up-sample the extracted feature map from the encoder 132 to generate the segmentation image 404. Upsampling may be performed, for example, by bilinear interpolation. A 1×1 convolutional layer may be applied to predict a class of each pixel. The decoder 134 may be structurally symmetrical with the encoder 132. The copy operation may link the corresponding down-sampling and up-sampling feature maps. The decoder 134 may restore the details and spatial dimensions of an image according to the image features, and obtain the result of the image segmentation mask. The features obtained by the encoder 132 may include less semantic information and may be denoted low-level features, whereas the features obtained by the decoder 134 may be denoted high-level features.

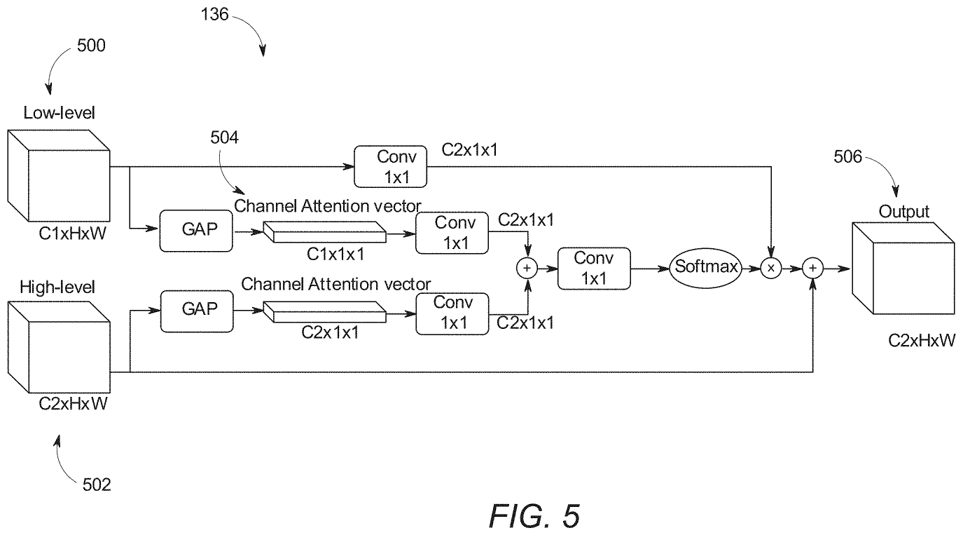

FIG. 5 illustrates details of the attention component 136 of the apparatus 100, in accordance with an example of the present disclosure.

Referring to FIG. 5, the attention component 136 may combine low-level feature maps 500 with high-level feature maps 502. The attention component 136 may perform global average pooling to extract global context and semantic information. The low-level feature maps may be multiplied by an attention vector 504 to generate an attentive feature map 506. In this regard, the attentive feature map may be determined by adding the high-level feature map.

With respect to a loss function, a multi-task loss may be applied by the loss analyzer 140 as a training objective. The training objective may learn to predict semantic labels for pixels and regress the locations for interest points. The loss analyzer 140 may learn to determine (e.g., estimate) the pixel-accurate location for all points of interest by means of separate heatmap regression tasks that may be based on mean squared error (MSE). The loss analyzer 140 may also output two segmentation maps. The first segmentation map may be used for segmenting background, rooms, and walls. The second segmentation map may be used for segmenting different icons and openings (e.g., windows and doors). The two segmentation tasks may be trained using cross-entropy loss as follows:

$${L}_{tot} = {L}_{H} + {L}_{S} \qquad Equation ( 2 )$$

$${L}_{S} = - {\sum }_{i = 1}^{C} {y}_{i} \cdot log ( {p}_{i} ) \qquad Equation ( 3 )$$

$${L}_{H} = - {\sum }_{i} ‖ {y}_{i} - \hat{{y}_{i}} ‖ \qquad Equation ( 4 )$$

For Equations (2)-(4), yᵢ may represent the label of the i^{th} element in the floor plan, C may represent the number of floor plan elements, and pᵢ may represent the prediction probability of the pixels of the i^{th} element. Lₛ may represent a cross-entropy loss for the segmentation part and is composed of two cross-entropy terms for room and icon segmentation tasks. Further, L_{H} may be utilized for training heatmap regressors, and yᵢ and ŷᵢ may represent the ground truth heatmap and predicted heatmap of location i. Equations (3) and (4) may be utilized for the loss function during model training.

Operation of the apparatus 100 may be evaluated by utilizing a large-scale floor plan dataset such as Cubicasa5K that includes, for example, 5000 samples annotated into over 80 floor plan object categories. For example, the dataset may include 5000 floor plans (e.g., with user-specified annotations) that are collected and reviewed from a larger set of 15,000 floor plan images. The dataset may be divided into three categories that include high quality architectural, high quality, and colorful floor plans including 3732, 992 and 276 floor plans respectively. The dataset may be divided into training, validation and test sets including 4200, 400, and 400 floor plans respectively. The annotations may be in scalable vector graphics (SVG) format, and include the semantic and geometric annotations for all of the floor plan elements.

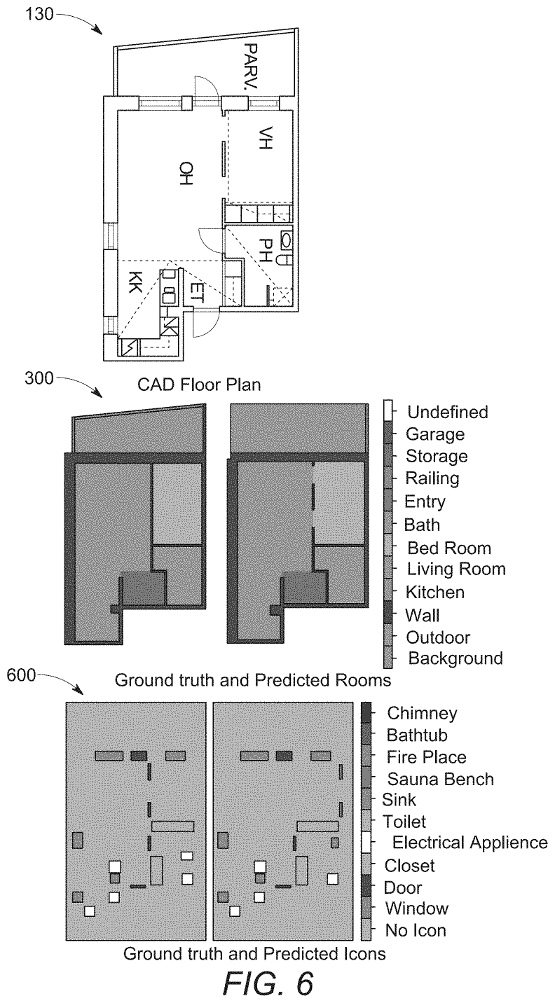

FIG. 6 illustrates results of parsing of CAD drawings for the stylization-based floor plan generation apparatus of FIG. 1, in accordance with an example of the present disclosure. In this regard, FIG. 6 shows results of execution of the CAD floor plan parser 128 to parse the CAD floor plan 130 to determine a room layout 300 for the CAD floor plan 130. FIG. 6 also shows results of execution of the CAD floor plan parser 128 to parse the CAD floor plan 130 to determine predicted icons 600 for the CAD floor plan 130.

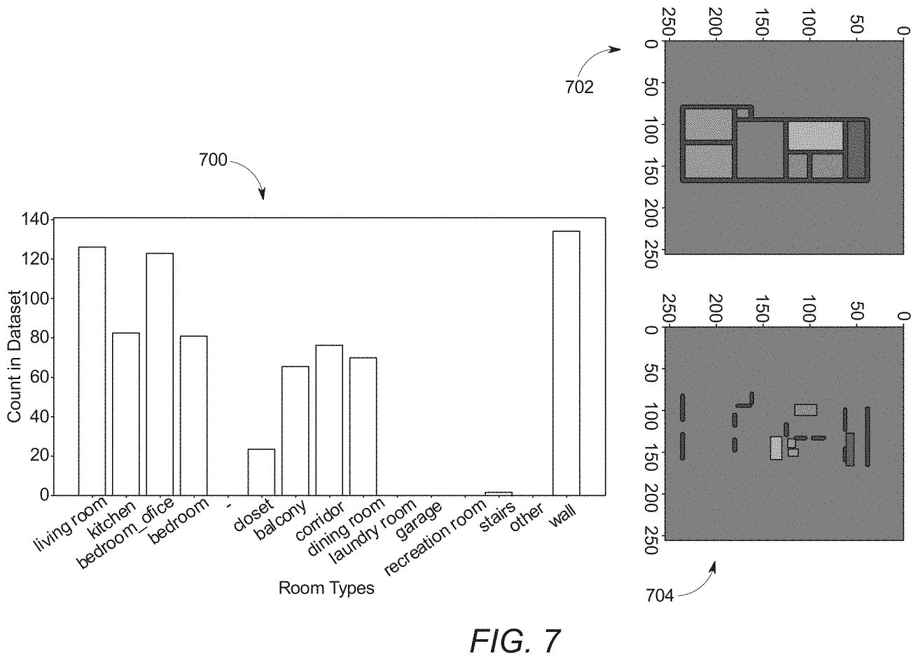

FIG. 7 illustrates a dataset for the apparatus 100, in accordance with an example of the present disclosure.

Referring to FIG. 7, an example of the dataset may include 155 total parsed floor plans, including 13 different types of rooms and 11 different types of furniture. A display of data allocation (e.g., count of living rooms, kitchens, etc.) for the dataset is shown at 700. With respect to pre-processing of data, segmented floor plans may be present in .tfrecords format. A boundary may include a fixed width of 5 pixels. A 5×5 cell may be analyzed for including all pixels with label of wall, and including one of the neighboring pixels with label of outside. Room and wall masks may be obtained using label values. A parsed image and an associated mask are shown at 702 and 704, respectively.

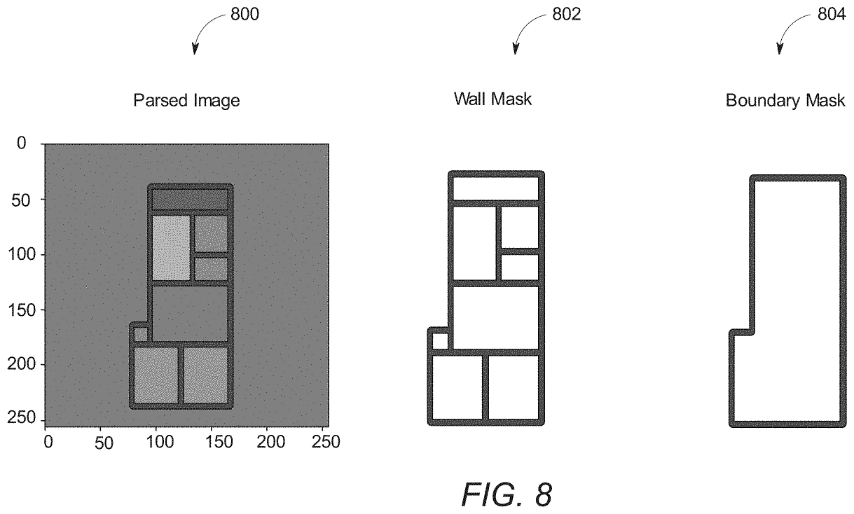

FIG. 8 illustrates pre-processed data for the apparatus 100, in accordance with an example of the present disclosure.

Referring to FIG. 8, the pre-processed data may include a parsed image at 800, a wall mask at 802, and a boundary mask at 804.

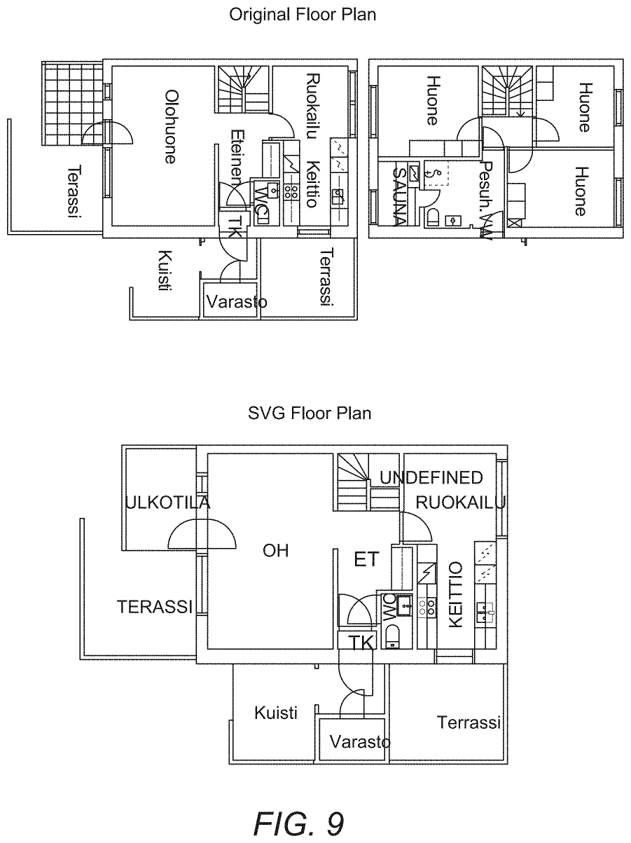

FIG. 9 illustrates Cubicasa5k snapshots to illustrate operation of the apparatus 100, in accordance with an example of the present disclosure.

Referring to FIG. 9, the Cubicasa5k snapshots may include an original floor plan at 900, and an SVG floor plan at 902. In this regard, the original floor plan at 900 may be utilized as an input to the model, and the SVG floor plan at 902 may include the ground truth annotation for rooms and icons.

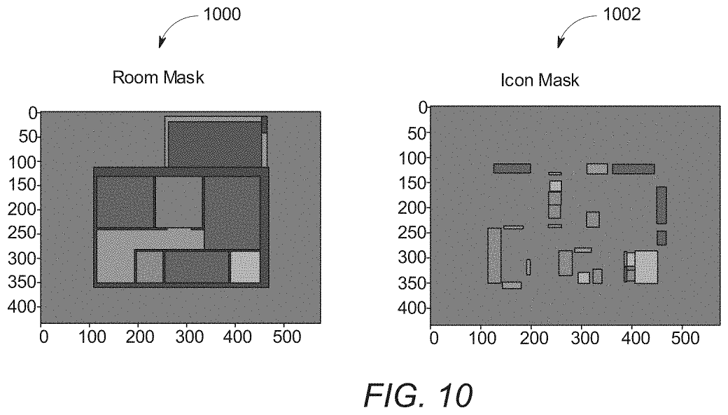

FIG. 10 illustrates Cubicasa5k pre-processing to illustrate operation of the apparatus 100, in accordance with an example of the present disclosure.

Referring to FIG. 10, with respect to Cubicasa5k pre-processing, an SVG file may include the ground truth segmentation maps of rooms and icons (e.g., furniture), as well as 21 heatmaps containing corners of wall, icons, doors and windows. With respect to Cubicasa5k pre-processing, the ground truth segmentation maps of rooms and icons are shown. The ground truth information in an SVG file may be read to visualize the segmentation, where a user may visualize the existing ground truth data before starting of training. Further, the ground truth segmentation maps for rooms and icons may be extracted using a SVG parser. Similarly, a wall mask may be extracted from the room masks. An example of a room mask is shown at 1000, and an icon mask is shown at 1002. The room mask and the icon mask may be utilized to facilitate visualization of the ground truth data. In this regard, the data that is stored in an SVG file may need to be presented visually for viewing of the segmentation maps.

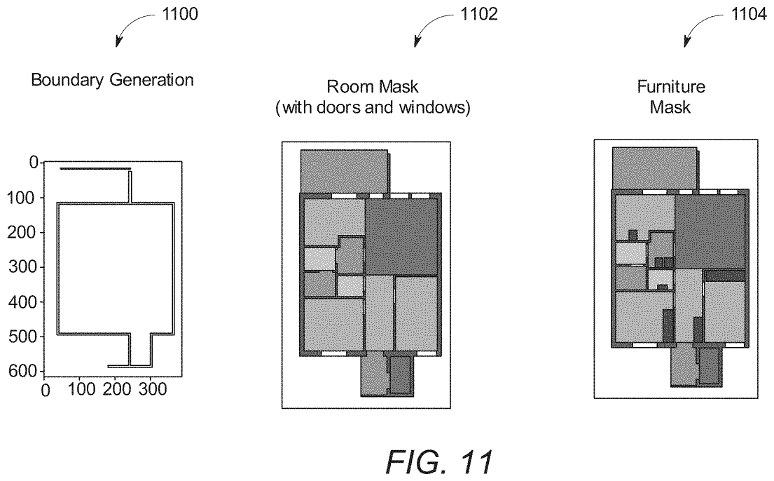

FIG. 11 illustrates Cubicasa5k pre-processed data to illustrate operation of the apparatus 100, in accordance with an example of the present disclosure.

Referring to FIG. 11, the Cubicasa5k pre-processed data may include boundary generation at 1100, room mask at 1102, and furniture mask at 1104. The Cubicasa5k pre-processed data including the boundary generation at 1100, room mask at 1102, and furniture mask at 1104 may be provided to a user for visualization purposes. In this regard, an associated SVG file may be parsed to extract information as shown in FIG. 11.

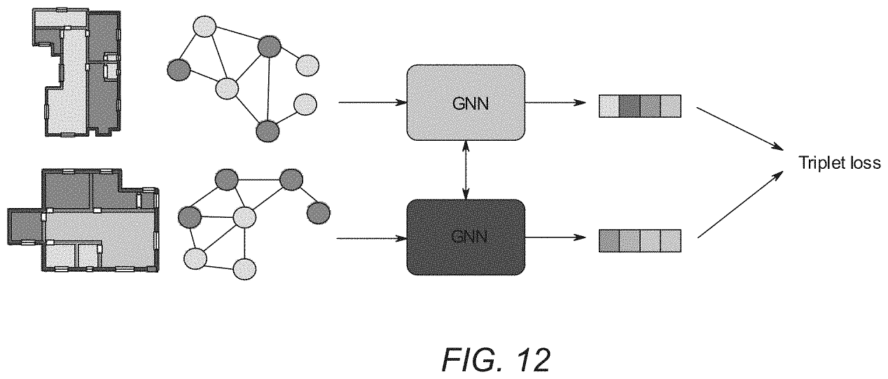

FIG. 12 illustrates similar layout extraction to illustrate operation of the apparatus 100, in accordance with an example of the present disclosure.

Referring to FIG. 12, similar layout extraction may be implemented to identify similar floor plans to a floor plan that has been selected. A floor plan (or floor plans) that is identified as being similar may be used as a reference. The similar layout extraction may be implemented as follows:

$${L}_{triplet} = {𝔼}_{( {G}_{1} , {G}_{2} , {G}_{3} )} [ max \{ 0 , d ( {G}_{1} , {G}_{2} ) - d ( {G}_{1} , {G}_{3} ) + γ \} ] \qquad Equation ( 5 )$$

For Equation (5), d(G₁, G₂) may represent the distance between the embedding value of graphs G₁ and G₂, and d(G₁, G₃) may represent the distance between the embedding value of graphs G₁ and G₃. These distance functions may be implemented as Euclidean or cosine. Further, γ may represent a specified threshold value. The similar floor plan identifier 142 may map the node and edge features to initial node and edge vectors through a Multi-layer Perceptron (MLP) as follows:

$${h}_{i}^{( 0 )} = {MLP}_{node} ( {x}_{i} ) , ∀ i ∈ V {e}_{ij} = {MLP}_{edge} ( {x}_{ij} ) , \\ ∀ ( i , j ) ∈ E . \qquad Equation ( 6 )$$

After ‘t’ iterations, a node's representation may capture dependence from all the nodes within the t-hop neighborhood. Formally, a node v's representations at t^{th} layer may be defined as follows:

$$\text{?} = MSG {.}^{( t )} ( {h}_{u}^{( t - 1 )} ) , u ∈ \{ 𝒩 ( v ) ⋃ v \} \qquad Equation ( 7 )$$

$$\text{?} = AGG {.}^{( t )} ( \{ {m}_{u}^{( t )} , u ∈ 𝒩 ( v ) \} , {m}_{v}^{( t )} ) \qquad Equation ( 8 )$$

$$\text{?} \text{indicates text missing or illegible when filed}$$

For Equations (6)-(8), hᵥ^{(t)} may represent the feature representation of node v at t^{th} layer, mᵤ^{(t)} may represent the transformed message from neighborhood node u, [symbol] (v) may represent the set of nodes adjacent to v, AGG may represent the aggregation function (implemented as mean of neighborhood messages), V may represent the set of vertices, E may represent the set of edges, and MSG may represent a message transformation function.

Next, the similar floor plan identifier 142 may utilize cross graph message propagation to match the node in one graph to nodes of another graph. Message information may be cross propagated from one node to another node (e.g., cross graph) as follows:

m_{i→j}=fₘ(hᵢ^{(t)},hⱼ^{(t)},eᵢⱼ) Equation (9)

The node similarity between two graphs may be measured, and the weights may be determined as follows:

s_{i→j}=fₛ(hᵢ^{(t)},hⱼ^{(t)}) Equation (10)

For Equation (10), hᵢ^{(t)} may represent a hidden state of node i of one graph, and hⱼ^{(t)} may represent a hidden state of node j of another graph. A hidden state of a node may be updated based on other information as follows:

$${h}_{j}^{( t + 1 )} = {f}_{u} ( {h}_{j}^{( t )} , {\sum }_{i} {m}_{i \to j} , {\sum }_{i} {𝓈}_{i \to j} ) \qquad Equation ( 11 )$$

Further, a similarity function may be implemented as follows:

$${w}_{i \to j} = \frac{exp ( s ( {h}_{i}^{( t )} , {h}_{j}^{( t )} ) )}{{\sum }_{j} exp ( s ( {h}_{i}^{( t )} , {h}_{j}^{( t )} ) )} \qquad Equation ( 12 )$$

For Equation (12), s(hᵢ^{(t)},hⱼ^{(t)}) may represent the Euclidean or cosine similarity between two hidden states. Equations (9)-(12) may be utilized to determine the embedding value for each node.

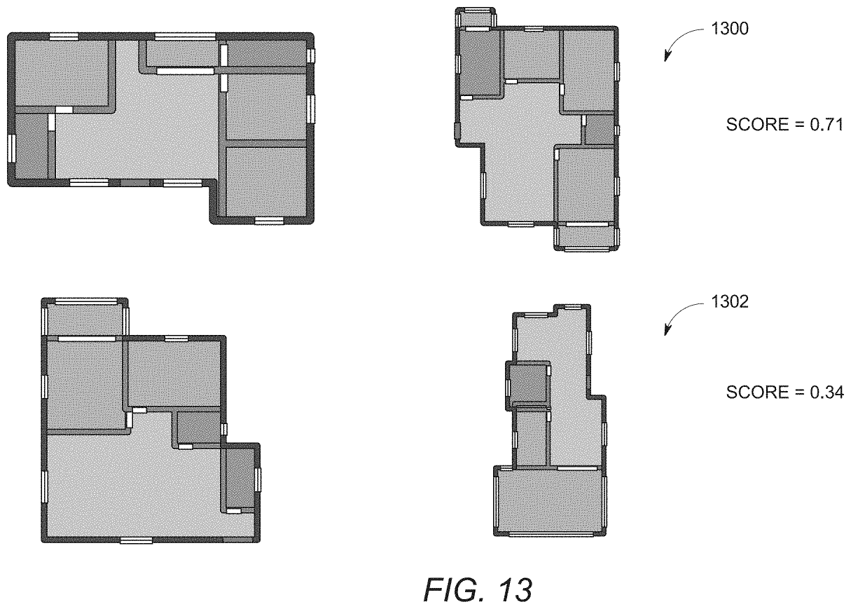

FIG. 13 illustrates results to illustrate operation of the apparatus 100, in accordance with an example of the present disclosure.

The results at 1300 determined by the similar floor plan identifier 142 show a score of 0.71, and the results at 1302 show a score of 0.34, thus indicating similarity of a generated floor plan to an existing floor plan.

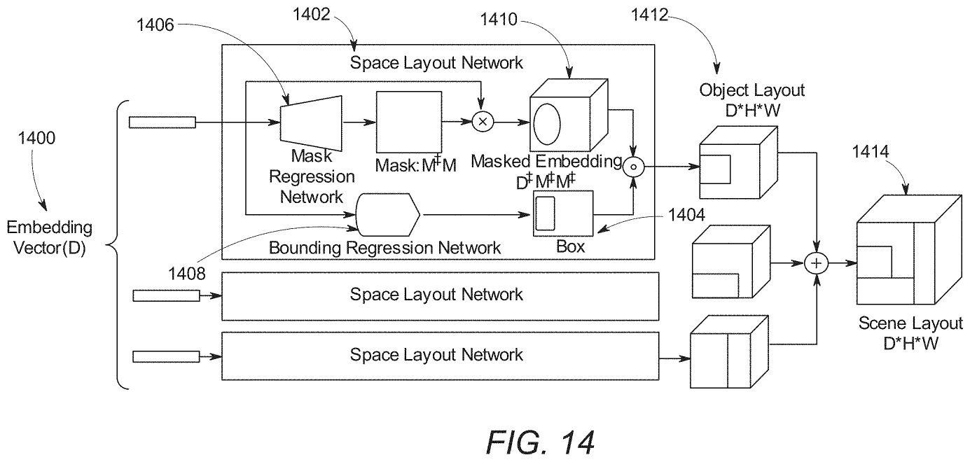

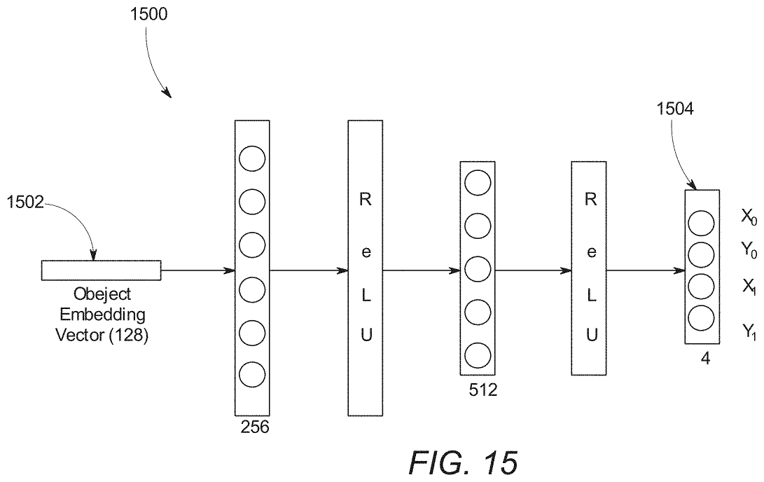

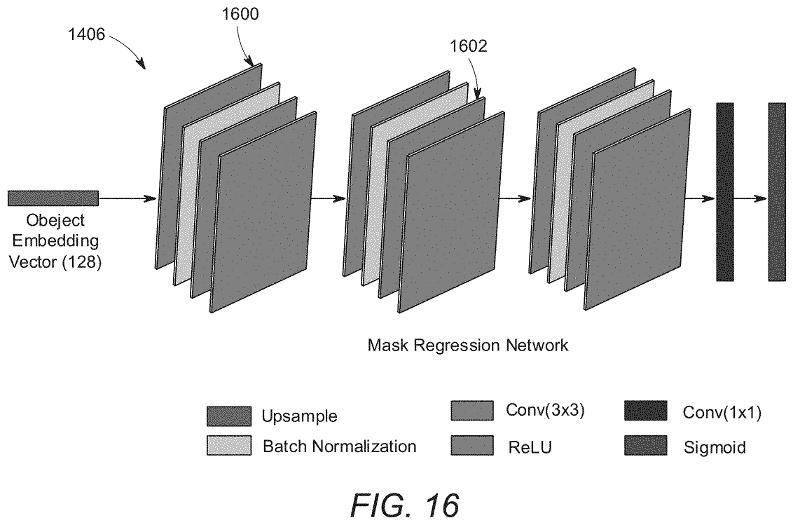

FIG. 14 illustrates details of the space layout network analyzer 114, in accordance with an example of the present disclosure. FIG. 15 illustrates a bounding regression network 1500 of the space layout network analyzer 114, in accordance with an example of the present disclosure. Further, FIG. 16 illustrates a mask regression network of the space layout network analyzer 114, in accordance with an example of the present disclosure.

Referring to FIG. 14, an embedding vector 1400, generated by graph convolutional message passing network analyzer 102 for each room type, may be passed to the space layout network analyzer 114 that may utilize a space layout network 1402 (e.g., three space layout networks shown), which may predict a layout for an object (e.g., room type). The space layout network analyzer 114 may predict a soft binary segmentation mask and a bounding box 1404 for each room type. The space layout network analyzer 114 may receive an embedding vector vᵢ of shape ‘D’ (128 for example) for room type rᵢ, and pass the embedding vector to a mask regression network 1406 (e.g., see also FIG. 16) to predict a soft binary mask rmᵢ of shape M*M and a box regression network 1408 to predict a bounding box bᵢ=(x₀; y₀; x₁; y₁), where x₀; x₁ are the left and right coordinates, and y₀; y₁ are the top and bottom coordinates of the box.

Referring to FIGS. 14 and 16, the mask regression network 1406 may include of a sequence of upsampling and convolution layers (e.g., 1600 and 1602) with sigmoid nonlinearity so that elements of the mask lie in the range (0; 1) and the box regression network may be a Multi-layer Perceptron (MLP). Upsampling may double the dimensions of an input. An upsample layer may include 2*2 nearest-neighbor upsampling. Convolution layers may be used to extract features and reduce the spatial dimensions.

With respect to FIG. 15, the bounding regression network 1500 may utilize a fully connected network (e.g., linear layer) having input embeddings of 128 (room type embedding) as shown at 1502. The input layer may be followed by several hidden layers of size 512, 256, and 4. The final hidden layer at 1504 may predict four coordinate values.

The embedding vector of each room type vᵢ may be multiplied element-wise with their mask an to generate a masked embedding of shape D*M*M at 1410, which may then be warped to the position of the bounding box using bi-linear interpolation to generate a room layout 1412. Space layout 1414 (e.g., also denoted scene layout) may represent the sum of all of the room layouts. A similar approach may be implemented to generate walls and door masks. During training, ground truth bounding boxes may be utilized for each room type to compare with the predicted bounding boxes. However, during inference time, the predicted bounding boxes hi may be utilized.

With respect to image synthesizing, the cascaded alignment layer analyzer 124 may synthesize a rasterized space layout 122 from the layout graph 106 and the input boundary feature map 126. The input boundary may be passed through a series of convolution and pooling layers to obtain the input boundary feature map 126. The cascaded alignment layer analyzer 124 may implement a series of convolutional alignment modules (CAM). A CAM may receive as input the space layout 122 and the input boundary feature map 126, and generate a new feature map which is twice the spatial size of the input boundary feature map 126. Each CAM may upsample the input boundary feature map 126 by a factor of two, and downsample the space layout 122 using average pooling to match the size of the upsampled feature map. The upsampled input boundary feature map 126 and the downsampled space layout 122 may be passed through a region of interest alignment layer, and further processed with two convolution layers to generate the floor plan 104. Region of interest Align, or RolAlign, may be an operation for extracting a small feature map from each region of interest (e.g., in detection and segmentation-based tasks). The RolAlign may be implemented to properly align the extracted features with the input. The RolAlign may use bilinear interpolation to compute the exact values of the input features.

With respect to loss function, the space layout network analyzer 114 may be trained to minimize the weighted sum of four losses. For example, bounding box loss (L_{b}) may determine the L₂ difference between ground truth and predicted bounding boxes. Mask loss (Lₘ) may determine the L₂ difference between ground truth and predicted masks. Pixel loss (Lₚ) may determine the L₂ difference between ground-truth and generated images. Overlap loss (Lₒ) may determine the overlap between the predicted room bounding boxes. The overlap between room bounding boxes may be specified to be as small as possible. Loss may be determined, for example, as: L_{T}=λ_{b}L_{b}+λₘLₘ+λₚLₚ+λₒLₒ, where λ_{b}=λₘ=λₚ=λ_{b0}=1.

The training dataset may include, for example, several thousand vector-graphics floor plans of residential (and/or non-residential) buildings designed by architects. Each floor plan may be represented as a four channel image. The first channel may store inside mask, the second channel may store boundary mask, the third channel may store wall mask, and the fourth channel may store room mask.

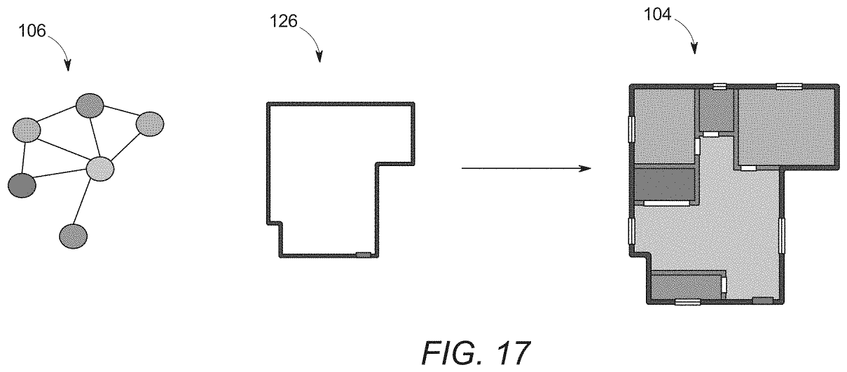

FIG. 17 illustrates an output of the stylization-based floor plan generation apparatus of FIG. 1, in accordance with an example of the present disclosure. In this regard. FIG. 17 shows the layout graph 106, the input boundary feature map 126, and the output floor plan 104.

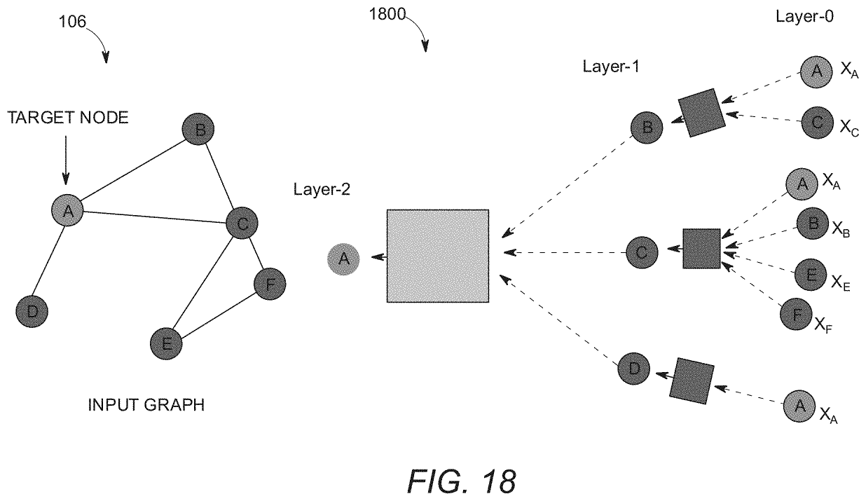

FIG. 18 illustrates a message passing network of the stylization-based floor plan generation apparatus 100, in accordance with an example of the present disclosure.

Referring to FIG. 18, with respect to the graph convolutional message passing network analyzer 102, the layout graph 106 may be passed through a series of graph convolution layers 1800 (e.g., a message passing network) which generates embedding vectors for each node (e.g., a room). In FIG. 18, X may represent the input features. Each layer may function as aggregation of information from the neighboring nodes. The graph convolutional message passing network analyzer 102 may utilize embedding layers to embed room types and relationships in the layout graph 106 to produce vectors of dimension Dᵢₙ=128. Given an input graph with vectors of dimension Dᵢₙ at each node and edge, the graph convolutional message passing network analyzer 102 may determine new vectors of dimension Dₒᵤₜ for each node and edge. Output vectors may be a function of a neighborhood of their corresponding inputs so that each graph convolution layer propagates information along edges of the layout graph 106.

With respect to the graph convolutional message passing network analyzer 102, a graph neural network (GNN) of the graph convolutional message passing network analyzer 102 may represent a deep neural network that uses a graph data structure to capture the dependence of data. The GNN may adopt a message-passing strategy to update the representation of a node by aggregating transformed messages (representations) of its neighboring nodes. After ‘t’ iterations of message passing, a node's representation may capture dependence from all the nodes within the t-hop neighborhood. Formally, a node v's representations at t^{th} layer may be defined as follows:

$${m}_{u}^{( t )} = MSG {.}^{( t )} ( {h}_{u}^{( t - 1 )} ) ,$$

$$u ∈ \{ 𝒩 ( v ) ⋃ v \} {h}_{v}^{( t )} = AGG {.}^{( t )} ( \{ {m}_{u}^{( t )} , u ∈ 𝒩 ( v ) \} , {m}_{v}^{( t )} )$$

In this regard, h^{(t)} may represent the feature representation of node v at t^{th} layer, m^{(t)} may represent the transformed message from neighborhood node u, and N (v) may represent the set of nodes adjacent to v. MSG may represent the message transformation at a particular node, and AGG may represent the aggregation function to capture the messages from neighboring nodes.

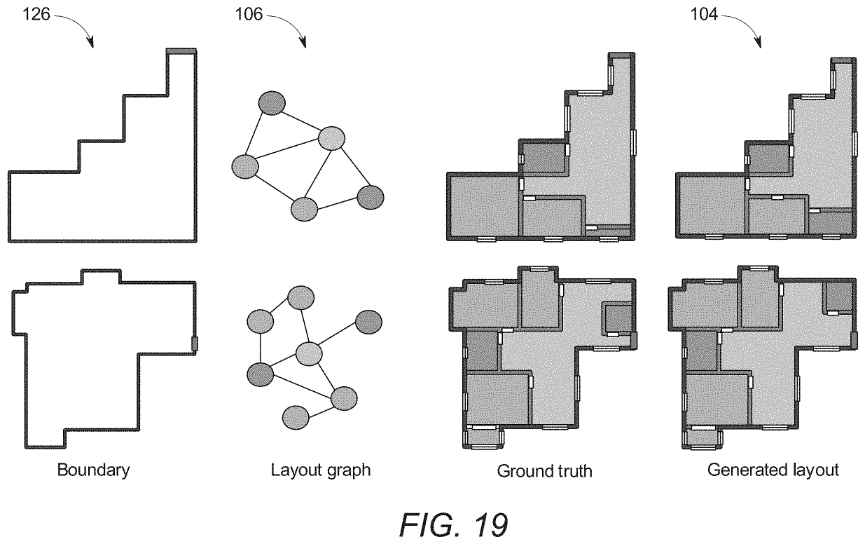

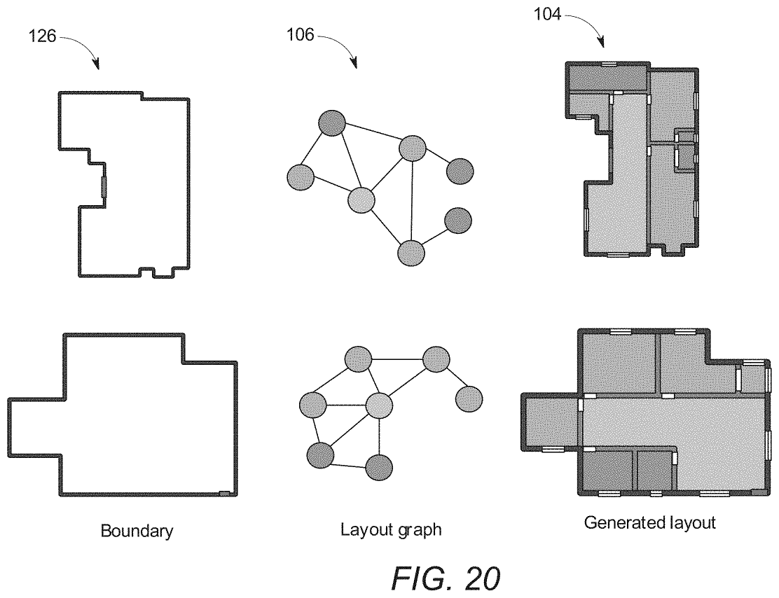

FIG. 19 illustrates examples of results generated by the apparatus 100, along with ground truth, in accordance with an example of the present disclosure. Further, FIG. 20 illustrates further examples of results generated by the apparatus 100, in accordance with an example of the present disclosure.

Referring to FIGS. 19-20, the floor plans generated by the apparatus 100 for various input boundaries and user constraints are shown. As shown, the floor plans generated by the apparatus 100 may locate the outline of the layout more precisely. Further, the floor plans generated by the apparatus 100 may meet size requirements of individual rooms and the spatial relations between rooms.

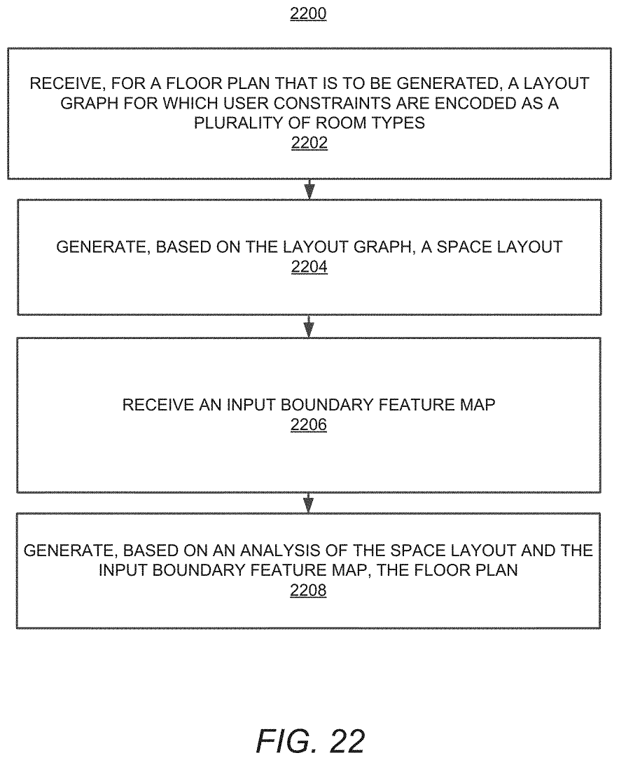

FIGS. 21-23 respectively illustrate an example block diagram 2100, a flowchart of an example method 2200, and a further example block diagram 2300 for stylization-based floor plan generation, according to examples. The block diagram 2100, the method 2200, and the block diagram 2300 may be implemented on the apparatus 100 described above with reference to FIG. 1 by way of example and not of limitation. The block diagram 2100, the method 2200, and the block diagram 2300 may be practiced in other apparatus. In addition to showing the block diagram 2100, FIG. 21 shows hardware of the apparatus 100 that may execute the instructions of the block diagram 2100. The hardware may include a processor 2102, and a memory 2104 storing machine readable instructions that when executed by the processor cause the processor to perform the instructions of the block diagram 2100. The memory 2104 may represent a non-transitory computer readable medium. FIG. 22 may represent an example method for stylization-based floor plan generation, and the steps of the method. FIG. 23 may represent a non-transitory computer readable medium 2302 having stored thereon machine readable instructions to provide stylization-based floor plan generation according to an example. The machine readable instructions, when executed, cause a processor 2304 to perform the instructions of the block diagram 2300 also shown in FIG. 23.

The processor 2102 of FIG. 21 and/or the processor 2304 of FIG. 23 may include a single or multiple processors or other hardware processing circuit, to execute the methods, functions and other processes described herein. These methods, functions and other processes may be embodied as machine readable instructions stored on a computer eadable medium, which may be non-transitory (e.g., the non-transitory computer readable medium 2302 of FIG. 23), such as hardware storage devices (e.g., RAM (random access memory), ROM (read only memory), EPROM (erasable, programmable ROM), EEPROM (electrically erasable, programmable ROM), hard drives, and flash memory). The memory 2104 may include a RAM, where the machine readable instructions and data for a processor may reside during runtime.

Referring to FIGS. 1-21, and particularly to the block diagram 2100 shown in FIG. 21, the memory 2104 may include instructions 2106 to receive, for a floor plan 104 that is to be generated, a layout graph 106 for which user constraints 108 are encoded as a plurality of room types 110.

The processor 2102 may fetch, decode, and execute the instructions 2108 to generate, based on the layout graph 106, embedding vectors 112 for each room type of the plurality of room types 110.

The processor 2102 may fetch, decode, and execute the instructions 2110 to determine, for each room embedding 116 from the layout graph 106, and based on an analysis of the embedding vectors 112 for each room type of the plurality of room types 110, bounding boxes 118 and segmentation masks 120.

The processor 2102 may fetch, decode, and execute the instructions 2112 to generate, by combining the bounding boxes 118 and the segmentation masks 120, a space layout 122.

The processor 2102 may fetch, decode, and execute the instructions 2114 to receive an input boundary feature map 126.

The processor 2102 may fetch, decode, and execute the instructions 2116 to generate, based on an analysis of the space layout 122 and the input boundary feature map 126, the floor plan 104.

Referring to FIGS. 1-20 and 22, and particularly FIG. 22, for the method 2200, at block 2202, the method may include receiving, for a floor plan 104 that is to be generated, a layout graph 106 for which user constraints 108 are encoded as a plurality of room types 110.

At block 2204, the method may include generating, based on the layout graph 106, a space layout 122.

At block 2206, the method may include receiving an input boundary feature map 126.

At block 2208, the method may include generating, based on an analysis of the space layout 122 and the input boundary feature map 126, the floor plan 104.

Referring to FIGS. 1-20 and 23, and particularly FIG. 23, for the block diagram 2300, the non-transitory computer readable medium 2302 may include instructions 2306 to receive, for a floor plan 104 that is to be generated, a layout graph 106 for which user constraints 108 are encoded as a plurality of room types 110.

The processor 2304 may fetch, decode, and execute the instructions 2308 to generate, based on the layout graph 106, a space layout 122.

The processor 2304 may fetch, decode, and execute the instructions 2310 to generate, based on an analysis of the space layout 122 and the input boundary feature map 126, the floor plan 104.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A stylization-based floor plan generation apparatus comprising:
at least one hardware processor;
a graph convolutional message passing network analyzer, executed by the at least one hardware processor, to:
receive, for a floor plan that is to be generated, a layout graph for which user constraints are encoded as a plurality of room types, wherein the user constraints include spatial connections therebetween; and
generate, based on the layout graph, embedding vectors for each room type of the plurality of room types;
a space layout network analyzer, executed by the at least one hardware processor, to:
determine, for each room embedding from the layout graph, and based on an analysis of the embedding vectors for each room type of the plurality of room types, bounding boxes and segmentation masks; and
generate, by combining the bounding boxes and the segmentation masks, a space layout; and
a cascaded alignment layer analyzer, executed by the at least one hardware processor, to:
receive an input boundary feature map; and
generate, based on an analysis of the space layout and the input boundary feature map, the floor plan.

2. The stylization-based floor plan generation apparatus according to claim 1, further comprising:
a computer-aided design (CAD) floor plan parser, executed by the at least one hardware processor, to:
receive a CAD floor plan; and
parse the CAD floor plan to determine a room layout for the CAD floor plan.

3. The stylization-based floor plan generation apparatus according to claim 2, wherein the CAD floor plan parser is executed by the at least one hardware processor to parse the CAD floor plan to determine the room layout for the CAD floor plan by:
extracting, by an encoder, a plurality of features from the CAD floor plan;
upsampling, by a decoder, the extracted plurality of features to generate a segmentation image; and
determining, by an attention component and from the segmentation image, semantic information and target features to generate the room layout for the CAD floor plan.

4. The stylization-based floor plan generation apparatus according to claim 3, wherein the attention component determines the semantic information and the target features by combining low-level feature maps with high-level feature maps.

5. The stylization-based floor plan generation apparatus according to claim 4, wherein the attention component determines the semantic information and the target features by multiplying the low-level feature maps by an attention vector.

6. The stylization-based floor plan generation apparatus according to claim 1, further comprising:
a layout graph generator, executed by the at least one hardware processor, to generate, from the room layout, the layout graph.

7. The stylization-based floor plan generation apparatus according to claim 1, further comprising:
a loss analyzer, executed by the at least one hardware processor, to analyze, for the generated floor plan, a cross-entropy loss.

8. The stylization-based floor plan aeneration apparatus according to claim 1, further comprising:
a similar floor plan identifier, executed by the at least one hardware processor, to:
determine node similarity between the generated floor plan and a plurality of existing floor plans;
generate, based on the determined node similarity between the generated floor plan and the plurality of existing floor plans, similarity scores;
identify, from the generated similarity scores, a highest similarity score; and
identify, based on the highest similarity score, a most similar existing floor plan.

9. The stylization-based floor plan generation apparatus according to claim 1, wherein the graph convolutional message passing network analyzer is executed by the at least one hardware processor to generate, based on the layout graph, the embedding vectors for each room type of the plurality of room types by:
utilizing a plurality of embedding layers to embed room types and relationships between rooms to generate vectors of a specified dimension.

10. The stylization-based floor plan generation apparatus according to claim 1, wherein the space layout network analyzer is executed by the at least one hardware processor to determine, for each room embedding from the layout graph, and based on the analysis of the embedding vectors for each room type of the plurality of room types, the bounding boxes and the segmentation masks by:
passing the embedding vectors to a box regression network to predict he bounding boxes.

11. The stylization-based floor plan generation apparatus according to claim 1, wherein the space layout network analyzer is executed by the at least one hardware processor to generate, by combining the bounding boxes and the segmentation masks, the space layout by:
multiplying an embedding vector for each room type by an associated mask to generate a plurality of masked embedding shapes;
utilizing bi-linear interpolation to modify the masked embedding shapes to a position of associated bounding boxes to generate room layouts; and
generating, based on a summation of the room layouts, the space layout.

12. A method for stylization-based floor plan generation, the method comprising:
receiving, by at least one hardware processor, for a floor plan that is to be generated, a layout graph for which user constraints are encoded as a plurality of room types, wherein the user constraints include spatial connections therebetween;
generating, by the at least one hardware processor, based on the layout graph, a space layout;
receiving, by the at least one hardware processor, an input boundary feature map; and
generating, by the at least one hardware processor, based on an analysis of the space layout and the input boundary feature map, the floor plan.

13. The method according to claim 12, wherein generating, by the at least one hardware processor, based on the layout graph, the space layout further comprises:
generating, by the at least one hardware processor, based on the layout graph, embedding vectors for each room type of the plurality of room types;
determining, by the at least one hardware processor, for each room embedding from the layout graph, and based on an analysis of the embedding vectors for each room type of the plurality of room types, bounding boxes and segmentation masks; and
generating, by the at least one hardware processor, by combining the bounding boxes and the segmentation masks, the space layout.

14. The method according to claim 12, further comprising:
receiving, by the at least one hardware processor, a CAD floor plan; and
parsing, by the at least one hardware processor, the CAD floor plan to determine a room layout for the CAD floor plan.

15. The method according to claim 13, wherein parsing, by the at least one hardware processor, the CAD floor plan to determine the room layout for the CAD floor plan further comprises:
extracting, by an encoder that is executed by the at least one hardware processor, a plurality of features from the CAD floor plan;
upsampling, by a decoder that is executed by the at least one hardware processor, the extracted plurality of features to generate a segmentation image; and
determining, by an attention component that is executed by the at least one hardware processor and from the segmentation image, semantic information and target features to generate the room layout for the CAD floor plan.

16. The method according to claim 15, wherein the attention component is executed by the at least one hardware processor to determine the semantic information and the target features by:
combining low-level feature maps with high-level feature maps; and
multiplying the low-level feature maps by an attention vector.

17. A non-transitory computer readable medium having stored thereon machine readable instructions, the machine readable instructions, when executed by at least one hardware processor, cause the at least one hardware processor to:
receive, for a floor plan that is to be generated, a layout graph for which user constraints are encoded as a plurality of room types, wherein the user constraints include spatial connections therebetween;
generate, based on the layout graph, a space layout; and
generate, based on an analysis of the space layout, the floor plan.

18. The non-transitory computer readable medium according to claim 17, wherein the machine readable instructions, when executed by the at least one hardware processor, further cause the at least one hardware processor to:
receive, an input boundary feature map; and
generate, based on an analysis of the space layout and the input boundary feature map, the floor plan.

19. The non-transitory computer readable medium according to claim 17, wherein the machine readable instructions to generate, based on the layout graph, the space layout, when executed by the at least one hardware processor, further cause the at least one hardware processor to:
generate, based on the layout graph, embedding vectors for each room type of the plurality of room types;
determine, for each room embedding from the layout graph, and based on an analysis of the embedding vectors for each room type of the plurality of room types, bounding boxes and segmentation masks; and
generate, by combining the bounding boxes and the segmentation masks, the space layout.

20. The non-transitory computer readable medium according to claim 19, wherein the machine readable instructions to generate, by combining the bounding boxes and the segmentation masks, the space layout, when executed by the at least one hardware processor, further cause the at least one hardware processor to:
multiply an embedding vector for each room type by an associated mask to generate a plurality of masked embedding shapes;
utilize bi-linear interpolation to modify the masked embedding shapes to a position of associated bounding boxes to generate room layouts; and
generate, based on a summation of the room layouts, the space layout.
